(19) United States
(12) Patent Application Publication
(10) Pub. No.: US 2009/0273281 A1
(43) Pub. Date: Nov. 5, 2009

(54) PHOTOCATHODE AND ELECTRON TUBE HAVING THE SAME

(75) Inventors: Minoru Niigaki, Hamamatsu-shi (JP); Toru Hirohata, Hamamatsu-shi (JP); Harumasa Yoshida, Hamamatsu-shi (JP); Hirofumi Kan, Hamamatsu-shi (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K., Hamamatsu-shi (JP)

(21) Appl. No.: 12/432,850

(22) Filed: Apr. 30, 2009

(30) Foreign Application Priority Data
May 2, 2008 (JP) P2008-120662

(51) Int. Cl. H01J 40/06; H01L 29/12

(52) U.S. Cl. 313/542; 257/11; 257/E29.068

(57) ABSTRACT

The photocathode of the present invention is provided with a supporting substrate composed of a single-crystal compound semiconductor, a light absorbing layer which is formed on the supporting substrate and smaller in an energy band gap than the supporting substrate to absorb incident light transmitted through the supporting substrate, thereby generating photoelectrons, and a surface layer which is formed on the light absorbing layer to lower a work function of the light absorbing layer, in which the supporting substrate comprises Al₍₁₋ₓ₎GaₓN (0≦X<1) and the light absorbing layer comprises a compound semiconductor composed of at least one material selected from the group consisting of Al, Ga and In, and N.

### BACKGROUND OF THE INVENTION

1. Field of the Invention

The present invention relates to a photocathode and an electron tube having the photocathode.

2. Related Background Art

In recent years, AlGaN-adopted photocathodes having particular sensitivity to ultraviolet light have advanced in development. Literature which has disclosed technologies on this type of AlGaN-adopted photocathodes includes Patent Document 1 (U.S. Pat. No. 4,616,248), Patent Document 2 (Japanese Published Unexamined Patent Application No. H10-188770) and Patent Document 3 (Japanese Published Unexamined Patent Application No. H10-188780).

Patent Document 1 has disclosed a photocathode which is provided with a sapphire substrate and a light absorbing layer formed on the sapphire substrate and made with AlGaN. Further, Patent Document 2 and Patent Document 3 have disclosed a photocathode which is provided with an LGO (LiGaO₂) substrate and an LAO (LiAlO₂) substrate close to AlGaN in lattice constant and light absorbing layers formed on the respective substrates and made with AlGaN.

### SUMMARY OF THE INVENTION

In the photocathode disclosed in Patent Document 1, there is installed a thick buffer layer for mitigating a large lattice mismatch between the sapphire substrate and the AlGaN-made light absorbing layer. However, where the sapphire substrate is used to form the AlGaN-made light absorbing layer thereon, a large lattice mismatch exists between the sapphire substrate and the light absorbing layer. Any attempt to mitigate the large lattice mismatch has so far failed in eliminating the dislocation or defective lamination resulting from the large lattice mismatch. This failure also exists in the photocathode of Patent Document 1 in which a buffer layer is installed between the sapphire substrate and the AlGaN-made light absorbing layer. Therefore, Patent Document 1 is unable to obtain a high-quality nitride photocathode, making it difficult to achieve a high-performance photocathode. In particular, where the photocathode of Patent Document 1 is used as a transmission-type photocathode, incident light is absorbed by the thick buffer layer, thereby making it more difficult to obtain a high-performance photocathode.

Further, in photocathodes disclosed in Patent Document 2 and Patent Document 3, the LGO substrate and the LAO substrate are used as the respective substrates. For this reason, although a lattice mismatch between one of the substrates and the AlGaN-made light absorbing layer or a lattice mismatch between the other substrate and the light absorbing layer is mitigated, these substrates easily undergo thermal decomposition during a high-temperature process for forming a light absorbing layer. And, for example, where a protective layer is formed, it is difficult to protect the substrates sufficiently. Still further, since they are thermally decomposed, it is impossible to obtain a high-performance photocathode.

The present invention has been made in view of the above problems, an object of which is to provide a high-performance photocathode and an electron tube having this photocathode.

In order to solve the above problems, the photocathode of the present invention is provided with a supporting substrate comprising a single-crystal compound semiconductor, a light absorbing layer which is formed on the supporting substrate, smaller in an energy band gap than the supporting substrate to absorb incident light transmitted through the supporting substrate, thereby generating photoelectrons, and a surface layer which is formed on the light absorbing layer to lower a work function of the light absorbing layer, in which the supporting substrate comprises Al₍₁₋ₓ₎GaₓN (0≦X<1) and the light absorbing layer comprises a compound semiconductor comprising at least one material selected from the group consisting of Al, Ga and In, and N.

In the photocathode of the present invention, the supporting substrate comprises Al₍₁₋ₓ₎GaₓN, the composition X of which is in a range of 0≦X<1. The supporting substrate composed of Al₍₁₋ₓ₎GaₓN is used, by which it is possible to obtain lattice matching between the light absorbing layer composed of the compound semiconductor and the supporting substrate, thereby eliminating the need for introducing a conventional thick buffer layer for mitigating lattice mismatch. The supporting substrate is not a film but a plate-like member. Further, the Al₍₁₋ₓ₎GaₓN semiconductor material is sufficiently stable in a high-temperature process for forming a light absorbing layer. Still further, the composition thereof, that is, X, is adjusted in a range of 0 or more to less than 1, by which the supporting substrate is given transmission properties with respect to light to be detected in an ultraviolet light ranged from approximately 200 nm to approximately 360 nm.

Further, the light absorbing layer which absorbs incident light to generate photoelectrons comprises a compound semiconductor composed of at least one material selected from the group consisting of Al, Ga and In, and N. Thereby, the photocathode can have sensitivity to ultraviolet light. Still further, since lattice matching can be obtained between the supporting substrate and the light absorbing layer, formation of a crystal defect of dislocation, etc., and lattice distortion are suppressed. As a result, it is possible to obtain a high-quality light absorbing layer and also improve quantum efficiency which is a ratio of the number of photoelectrons emitted outside a photocathode to the number of photons made incident into the photocathode.

Further, the surface layer which lowers a work function of the light absorbing layer is provided on the light absorbing layer. Thereby, a vacuum level on the surface of the light absorbing layer is decreased to further increase the efficiency of emitting photoelectrons. Therefore, according to the photocathode of the present invention, it is possible to obtain a high-performance photocathode.

Further, it is preferable that the surface layer includes one type or more of alkaline metals or alkaline metal compounds. It is also preferable that the composition (ratio) X of Al₍₁₋ₓ₎GaₓN which forms the supporting substrate is within a range of 0≦X<0.7. Thereby, the supporting substrate is given transmission properties with respect to light to be detected in an ultraviolet light range from approximately 200 nm to approximately 280 nm.

Still further, it is preferable that the photocathode of the present invention further comprises a buffer layer which is interposed between the supporting substrate and the light absorbing layer and has an energy band gap not more than that of the supporting substrate. In this case, although the buffer layer absorbs the mismatch, there is a small difference in lattice constant (ratio) between the supporting substrate and the light absorbing layer. It is therefore, possible to make the buffer layer thin and also suppress light absorption by the buffer layer, thereby improving the quantum efficiency.

In addition, the electron tube of the present invention comprises the above described photocathode, an anode for collecting electrons emitted from the photocathode, and a vacuum vessel which accommodates the photocathode and the anode. The electron tube of the present invention is provided with a high-performance photocathode, and this high-performance photocathode has a high photoelectric conversion quantum efficiency. Therefore, according to the present electron tube, a highly accurate measurement can be made to obtain a high-performance electron tube.

The photocathode of the present invention is able to provide a high-performance photocathode and an electron tube having the photocathode.

### BRIEF DESCRIPTION OF THE DRAWINGS

FIG. 1 is a cross sectional view showing a constitution of a photocathode of a first embodiment.

FIG. 2 is a graphic chart showing spectral sensitivity characteristics of the photocathode in FIG. 1.

FIG. 3 is a graphic chart showing the spectral sensitivity characteristics of the photocathode in FIG. 1.

FIG. 4 is a graphic chart showing the spectral sensitivity characteristics of the photocathode in FIG. 1.

FIG. 5 is a graphic chart showing the spectral sensitivity characteristics of the photocathode in FIG. 1.

FIG. 6 is a cross sectional view showing a constitution of the photocathode of a second embodiment.

FIG. 7 is a drawing for explaining a cross-sectional constitution of the first embodiment of an electron tube 5 which has the photocathode in FIG. 1.

FIG. 8 is a drawing for explaining a cross-sectional constitution of the first embodiment of an electron tube 7 having the photocathode in FIG. 1.

### DESCRIPTION OF THE PREFERRED EMBODIMENTS

Hereinafter, a detailed description will be given for a preferred embodiment of the present invention by referring to the attached drawings. In addition, in the description, the same reference numerals will be given for the same or similar elements, with overlapped description omitted.

### First Embodiment

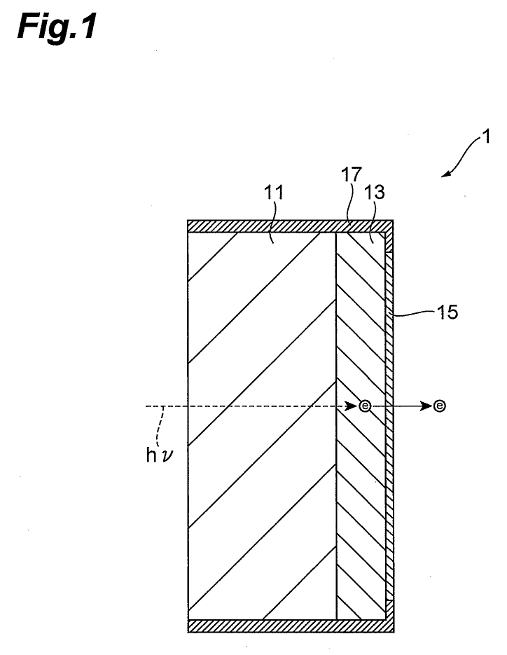

FIG. 1 is a cross sectional view of a photocathode 1 of the first embodiment in the present invention. As shown in FIG. 1, the photocathode 1 is of a transmission type and provided with a supporting substrate 11 as well as a light absorbing layer 13 and a surface layer 15 formed sequentially on the supporting substrate 11. The photocathode 1 is provided with an electrode 17 which covers the periphery of an electron emitting face on a surface layer 15 and side faces of the surface layer 15, the light absorbing layer 13 and the supporting substrate 11.

The supporting substrate 11 comprises a single crystal Al₍₁₋ₓ₎GaₓN which is a single-crystal compound semiconductor, and a composition ratio of X is within a range of 0≦X<1 and more preferably within a range of 0≦X<0.7. The supporting substrate 11 absorbs light, which is shorter in wavelength than wavelength λ₁₁ corresponding to an energy band gap of Al₍₁₋ₓ₎GaₓN decided by a value of X, thereby transmitting light longer in wavelength than wavelength λ₁₁.

The light absorbing layer 13 is formed directly on the supporting substrate 11 and made with a single crystal Inₓ₁(Al_{y1}Ga_{1-y1})₁₋ₓ₁N, and composition ratios of Inₓ₁(Al_{y1}Ga_{1-y1})₁₋ₓ₁N are within a range of 0≦x1≦0.5 and within a range of 0≦y1≦1. Further, the light absorbing layer 13 has an energy band gap smaller than that of the supporting substrate 11.

The light absorbing layer 13 absorbs light, which is shorter in wavelength than wavelength λ₁₃ corresponding to an energy band gap of Inₓ₁(Al_{y1}Ga_{1-y1})₁₋ₓ₁N decided by values of x1 and y1 in incident light transmitted through the supporting substrate 11, thereby generating photoelectrons. In addition, light having a wavelength longer than the wavelength λ₁₃ is to transmit through the light absorbing layer 13. Therefore, the wavelength of light to be detected for which the photocathode 1 has sensitivity covers a range of wavelength λ₁₁ corresponding to an energy band gap of the supporting substrate 11 to the wavelength λ₁₃ corresponding to an energy band gap of the light absorbing layer 13. More specifically, the supporting substrate 11 decides a lower limit of the wavelength of light to be detected for which the photocathode 1 has sensitivity, while the light absorbing layer 13 decides an upper limit of the wavelength of light to be detected which the photocathode 1 has sensitivity.

A compound layer composed of Cs and O is formed as a surface layer 15 on the light absorbing layer 13. The surface layer 15 will lower a work function of the surface of the light absorbing layer 13. The surface layer 15 is generated on the light absorbing layer 13, with a vacuum level on the surface of the light absorbing layer 13 decreased, and provided with functions of increasing an efficiency of emitting photoelectrons which have arrived at the surface of the light absorbing layer 13.

Hereinafter, a description will be given for the operation of the photocathode 1 by referring to FIG. 1. When light to be detected (hv) is made incident from the supporting substrate 11 of the photocathode 1 in a direction indicated by the arrow, the light to be detected is hardly absorbed by the supporting substrate 11 but is transmitted due to the fact that the supporting substrate 11 is translucent to the light to be detected. In this case, since the supporting substrate 11 is composed of a single crystal, the light to be detected is not scattered by a grain boundary. More specifically, the light to be detected is not influenced by a change in light path to transmit through the supporting substrate 11.

The light to be detected which has transmitted through the supporting substrate 11 is absorbed by the light absorbing layer 13 made with a single crystal and also lattice-matched to the supporting substrate 11. In this case, since the occurrence of a crystal defect based on lattice mismatch with the supporting substrate 11 is suppressed on the light absorbing layer 13, a recombination level derived from the crystal defect is hardly formed in a forbidden band of the light absorbing layer 13. Therefore, when the light to be detected is absorbed by the light absorbing layer 13 to excite electrons of the light absorbing layer 13, such a probability is greatly reduced that the electrons are captured by the recombination level. Thus, the light to be detected is substantially absorbed by the light absorbing layer 13 to excite the electrons, and the thus excited electrons are then converted to photoelectrons. Further, photoelectrons generated on the light absorbing layer 13 will move inside the light absorbing layer 13 due to dispersion and reach the surface of the light absorbing layer 13. Since a work function of the surface of the light absorbing layer 13 is lowered in advance by the surface layer 15, the photoelectrons which have reached the surface of the light absorbing layer 13 are efficiently emitted outside.

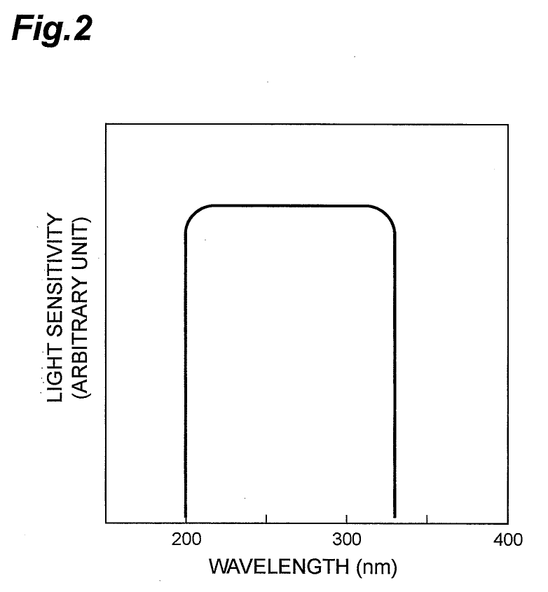

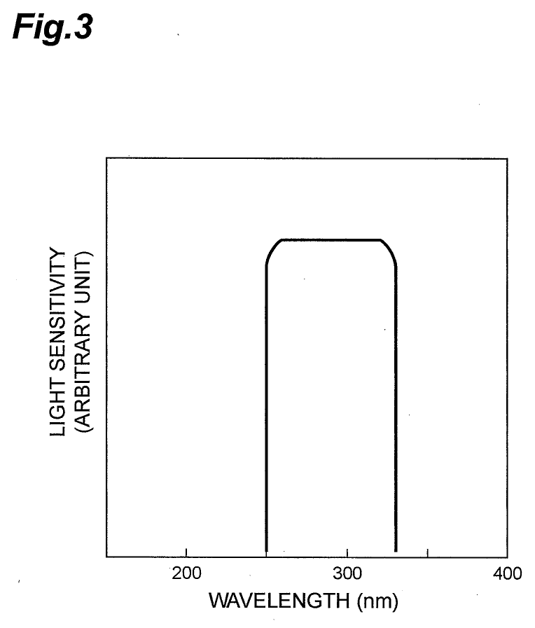

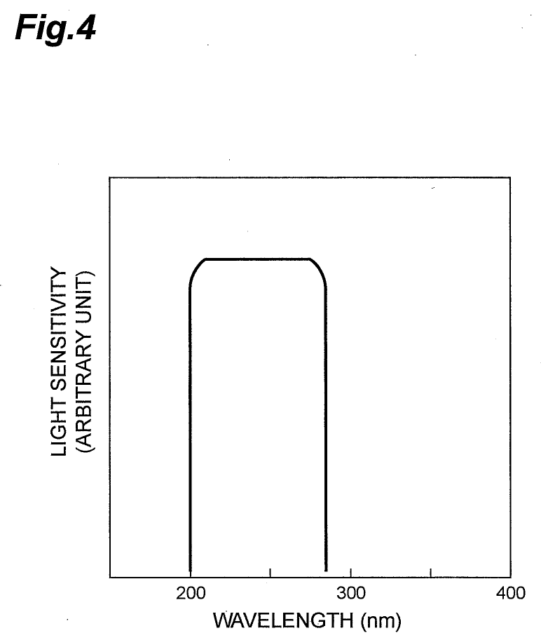

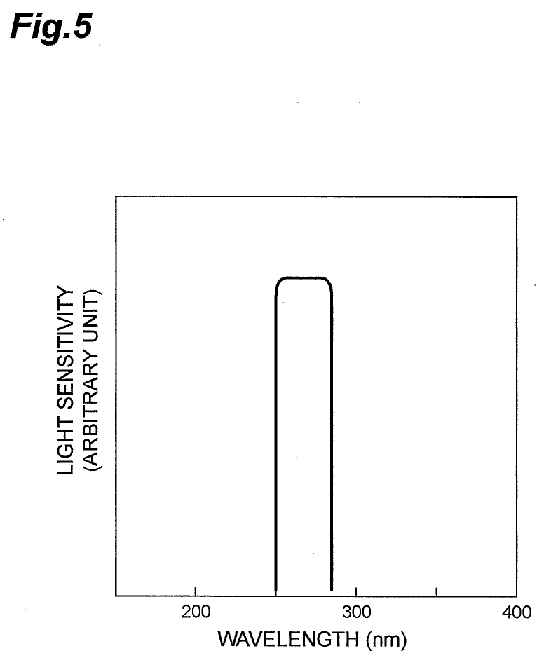

FIG. 2 through FIG. 5 are graphic charts showing the spectral sensitivity characteristics of the photocathode 1 of the embodiments. In these embodiments, semiconductor materials constituting respectively the supporting substrate 11 and the light absorbing layer 13 are changed in composition. More specifically, shown are spectral sensitivity characteristics of the photocathode 1 in FIG. 2 (example 1) where the supporting substrate 11 and the light absorbing layer 13 comprise respectively AlN and GaN, in FIG. 3 (example 2) where the supporting substrate 11 and the light absorbing layer 13 comprises respectively Al_{0.4}Ga_{0.6}N and GaN, in FIG. 4 (example 3) where the supporting substrate 11 and the light absorbing layer 13 comprises respectively AlN and Al_{0.3}Ga_{0.7}N, and in FIG. 5 (example 4) where the supporting substrate 11 and the light absorbing layer 13 comprises respectively Al_{0.4}Ga_{0.6}N and Al_{0.3}Ga_{0.7}N.

Combinations of materials in the above described photocathode are summarized as follows.

### EXAMPLE 1

### FIG. 2

Light absorbing layer: GaN[=Inₓ₁(Al_{y1}Ga_{1-y1})₁₋ₓ₁N, composition ratio x1=0,y1=0]
Supporting substrate: AlN[=Al₍₁₋ₓ₎GaₓN], composition ratio X=0]

### EXAMPLE 2

### FIG. 3

Light absorbing layer: GaN[=Inₓ₁(Al_{y1}Ga_{1-y1})₁₋ₓ₁N, composition ratio x1=0,y1=0]
Supporting substrate: Al_{0.4}Ga_{0.6}N[=Al₍₁₋ₓ₎GaₓN], composition ratio X=0.6]

### EXAMPLE 3

### FIG. 4

Light absorbing layer: Al_{0.3}Ga_{0.7}N[=Inₓ₁(Al_{y1}Ga_{1-y1})₁₋ₓ₁N, composition ratio x1=0, y1=0.3]
Supporting substrate: AlN[=Al₍₁₋ₓ₎GaₓN), composition ratio X=0]

### EXAMPLE 4

### FIG. 5

Light absorbing layer: Al_{0.3}Ga_{0.7}N[=Inₓ₁(Al_{y1}Ga_{1-y1})₁₋ₓ₁N, composition ratio x1=0, y1=0.3]
Supporting substrate: Al_{0.4}Ga_{0.6}N[=Al₍₁₋ₓ₎GaₓN], composition ratio X=0.6]

In FIG. 2 and FIG. 3, the respective light absorbing layers 13 are made with GaN, with the composition of the material being the same. The wavelength corresponding to an energy band gap of GaN is approximately 360 nm. Therefore, in the photocathodes 1 having the characteristics in FIG. 2 and FIG. 3, light to be detected is to have the same sensitivity of an upper limit wavelength (approximately 360 nm). On the other hand, since the photocathodes 1 having the characteristics in FIG. 2 and FIG. 3 are different in composition of a material of the supporting substrate 11, light to be detected for which the respective photocathodes 1 has sensitivity is different in a lower limit wavelength.

In FIG. 2, the supporting substrate 11 comprises AlN and the lower limit wavelength thereof is approximately 250 nm which is a wavelength corresponding to an energy band gap of AlN.

In FIG. 3, the supporting substrate 11 comprises Al_{0.4}Ga_{0.6}N, and the lower limit wavelength thereof is approximately 250 nm which is a wavelength corresponding to an energy band gap of Al_{0.4}Ga_{0.6}N.

Further, in FIG. 4 and FIG. 5, both of the light absorbing layers 13 comprise Al_{0.3}Ga_{0.7}N, with the composition of the material being the same. The wavelength corresponding to an energy band gap of Al_{0.3}Ga_{0.7}N is approximately 280 nm. Therefore, the photocathodes 1 in FIG. 4 and FIG. 5 are to have sensitivity in which an upper limit wavelength (approximately 280 nm) of light to be detected is the same.

The supporting substrates 11 in FIG. 4 and FIG. 5 have the same composition of material as the respective supporting substrates 11 in FIG. 2 and FIG. 3. Therefore, the photocathode 1 of FIG. 4 is approximately 200 nm in lower limit wavelength of sensitivity to light to be detected as with the photocathode 1 of FIG. 2, while the photocathode 1 of FIG. 5 is approximately 250 nm in lower limit wavelength of sensitivity to light to be detected, as with the photocathode 1 of FIG. 3.

As described above, the supporting substrate 11 is changed in composition of the material from AlN to Al_{0.4}Ga_{0.6}N, by which light to be detected for which the photocathode 1 has sensitivity can be changed in lower limit of the wavelength from 200 nm to 250 nm.

Further, it is apparent that the light absorbing layer 13 is changed in composition of material from GaN to Al_{0.3}Ga_{0.7}N, by which light to be detected for which the photocathode 1 has sensitivity can be changed in upper limit of the wavelength from approximately 360 nm to 280 nm.

The results shown in FIG. 2 to FIG. 5 have confirmed that where a composition X of the supporting substrate 11 comprising Al₍₁₋ₓ₎GaₓN is adjusted within a range of 0 or more to less than 1, it is possible to give transmission properties to light to be detected in an ultraviolet light range from approximately 200 nm to approximately 360 nm, and where the composition X is adjusted within a range of 0 or more to less than 0.7, it is possible to give transmission properties to light to be detected in an ultraviolet light range from approximately 200 nm to approximately 360 nm.

In the photocathode 1 of the present embodiment, the supporting substrate 11 comprises Al₍₁₋ₓ₎GaₓN (0≦X<0.7), and the light absorbing layer 13 comprises Inₓ₁(Al_{y1}Ga_{1-y1})₁₋ₓ₁N. Therefore, unlike a conventional case, without installing a thick buffer layer which will absorb light to be detected, it is possible to obtain lattice matching between the supporting substrate 11 and the light absorbing layer 13. Accordingly, lattice distortion is suppressed, thus making it possible to provide a high-quality light absorbing layer 13. As a result, it is possible to increase the quantum efficiency.

Further, an Al₍₁₋ₓ₎GaₓN semiconductor material which forms the supporting substrate 11 is sufficiently stable in a high-temperature process for forming the light absorbing layer 13.

Further, the composition ratio of X is adjusted within a range of 0 or more to less than 0.7, by which it is possible to give transmission properties to light to be detected in an ultraviolet light range from approximately 200 nm to approximately 280 nm (refer to FIG. 1).

Still further, there is provided on the light absorbing layer 13 a surface layer 15 which is composed of Cs and O to lower a work function of the light absorbing layer 13. A depletion layer is formed in the vicinity of a boundary face between the surface layer 15 and the light absorbing layer 13 by the surface layer 15, and an energy band is curved so that an electron affinity with the light absorbing layer 13 is apparently negative. Therefore, photoelectrons reaching the boundary face between the surface layer 15 and the light absorbing layer 13 will be easily emitted outside. More specifically, a vacuum level on the surface of the light absorbing layer 13 can be decreased by the surface layer 15, thus making it possible to increase the efficiency of the photoelectron emission. A photocathode having a light sensitivity in the wavelength range of light to be detected up to approximately 280 nm in particular is called a solar blind-type photocathode and used effectively in measuring ultraviolet light under sunlight.

In addition, since the supporting substrate 11 is made with a single crystal, the quality of the light absorbing layer 13 can be favorably subjected to epitaxial growth on the single crystal. And, formation of a crystal defect such as dislocation between the supporting substrate 11 and the light absorbing layer 13 can be suppressed, thus making it possible to increase the quantum efficiency.

### Second Embodiment

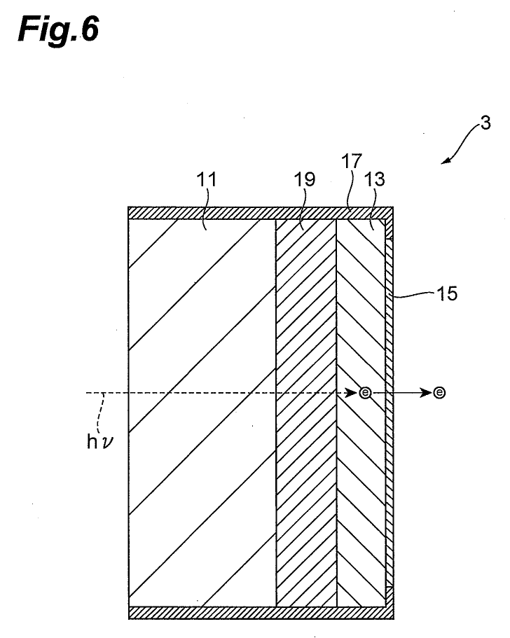

FIG. 6 is a cross sectional view of a photocathode 3 of the second embodiment in the present invention. The photocathode 3 is different in constitution from the photocathode 1 of the first embodiment in that the buffer layer 19 is additionally provided between the supporting substrate 11 and the light absorbing layer 13. Since other constitutions are the same as constitution of the photocathode 1, the same reference numerals will be given for the same or similar elements, with overlapped description omitted.

The buffer layer 19 is in contact with both the supporting substrate 11 and the light absorbing layer 13 and comprising Inₓ₂(Al_{y2}Ga_{1-y2})₁₋ₓ₂N. The composition X of Inₓ₂(Al_{y2}Ga_{1-y2})₁₋ₓ₂N is preferably within a range of 0≦x2≦0.5 and within a range 0<y2≦1, and more preferably within a range of x1≧x2 and within a range of y1≦y2 in view of energy absorption efficiency. Further, an energy band gap of the buffer layer 19 is not more than that of the supporting substrate 11 but greater than that of the light absorbing layer 13. Therefore, incident light which has transmitted through the supporting substrate 11 and the buffer layer 19 is partially absorbed by the light absorbing layer 13 to excite photoelectrons.

The photocathode 3 is, as described above, additionally provided with the buffer layer 19 between the supporting substrate 11 and the light absorbing layer 13, thus making it possible to obtain the same effect as the first embodiment and also decrease dislocation and other defects generating from the supporting substrate 11. Therefore, the light absorbing layer 13 formed on the buffer layer 19 is less influenced by dislocation or defects of the supporting substrate 11 and improved in quality. Thereby, it is possible to improve the quantum efficiency and also obtain the photocathode 1 which is higher in sensitivity.

In particular, due to a smaller ratio (ΔL/L11) of a difference AL (=L13−L11) in lattice constant between the lattice constant L11 of the supporting substrate 11 and the lattice constant L13 of the light absorbing layer 13 to the lattice constant L11 of the supporting substrate 11, the buffer layer 19 can be made thin, thereby suppressing light absorbed by the buffer layer 19 and also improving the quantum efficiency.

The ratio (ΔL/L11) of a difference in lattice constant ΔL is preferably within a range of −0.1≦ΔL/L11≦+0.1. In addition, the lattice constant, which is great in atomic radius, is increased with an increase in composition ratio and decreased with a decrease in composition ratio. Further, in general, a lattice constant is inversely proportional to an energy band gap. Thus, the inverse proportional relationship or a relative graphic chart of an energy band gap and lattice constant which has been described in general textbooks of compound semiconductors can be used to adjust an energy band gap of each layer to a desired value.

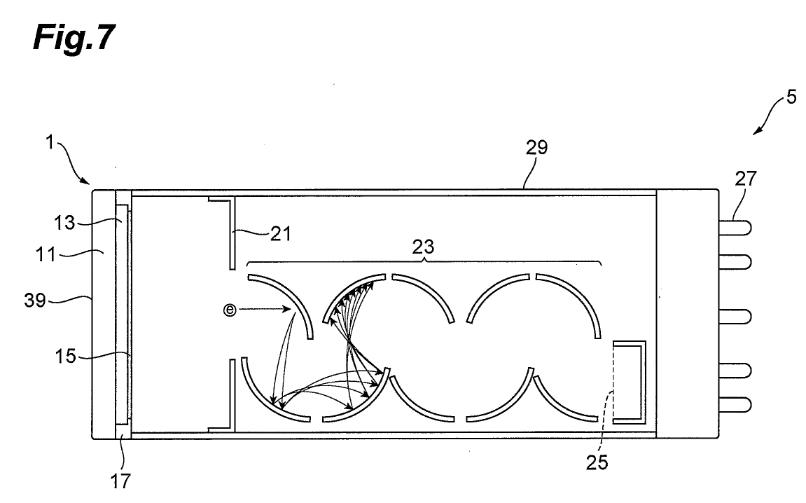

FIG. 7 is a drawing for explaining a cross-sectional constitution of one embodiment of an electron tube 5 equipped with a photocathode 1. The electron tube 5 in FIG. 7 is a photomultiplier and constituted with the photocathode 1 for converting light to be detected which is made incident from outside to photoelectrons and emitting them, a focusing electrode 21 for focusing photoelectrons emitted from the photocathode 1, a secondary electron multiplying portion 23 for subjecting the photoelectron focused by the focusing electrode 21 to secondary electron multiplication, an anode 25 for collecting the thus multiplied secondary electrons and a vacuum vessel 29 which is a vessel for accommodating them in a vacuum state. These elements are arranged inside the vacuum vessel 29 at predetermined intervals in the order of the photocathode 1, the focusing electrode 21, the secondary electron multiplying portion 23 and the anode 25 from the side to which light to be detected is made incident. A stem 27 is provided on one end of the vacuum vessel 29 opposing the photocathode 1, thereby electrically connecting the inside of the vacuum vessel 29 to the outside thereof.

The photocathode 1 will emit photoelectrons generated therein toward the secondary electron multiplying portion 23 in response to light to be detected which is made incident from outside. A region where no light absorbing layer 13 is formed on the supporting substrate 11 of the photocathode 1 is in contact with the other opening end of the vacuum vessel 29 and the photocathode 1 is fixed to a side tube of the vacuum vessel 29 in such a manner that the supporting substrate 11 is given as an entrance window 39 of the electron tube 5. The focusing electrode 21 focuses the photoelectrons emitted from the photocathode 1 toward the secondary electron multiplying unit 23.

The secondary electron multiplying portion 23 is constituted with 10 dynode stages (in sequence, a first dynode to a tenth dynode are arranged from the incident side of light to be detected) to which voltage is applied so as to increase every 100V, for example, in a stepwise manner from the side to which the light to be detected is made incident, accelerating the photoelectrons focused by the focusing electrode 21 due to a difference in potential between mutually adjacent dynodes to multiply them sequentially during passage through the secondary electron multiplying portion 23, thereby emitting secondary electrons. In addition, a predetermined voltage is applied also between the photocathode 1 and the first dynode. The anode 25 collects secondary electrons emitted from the secondary electron multiplying portion 23.

The stem 27 applies a predetermined voltage to each of the dynodes from outside and also outputs as a photoelectric current secondary electrons collected by the anode 25 outside the vacuum vessel 29.

Next, a description will be given for the operation of the electron tube 5 which is a photomultiplier. Incident light made incident into the photocathode 1 by way of the entrance window 39 is transmitted through the supporting substrate 11 and absorbed by the light absorbing layer 13 to excite photoelectrons inside the light absorbing layer 13. The thus excited photoelectrons will move inside the light absorbing layer 13 in accordance with the diffusion and internal field and reach the surface of the light absorbing layer 13. Since a work function of the surface is decreased by the surface layer 15, the photoelectrons can be easily emitted in a vacuum. The photoelectrons emitted in a vacuum are collected by the focusing electrode 21 and made incident into a first dynode of the secondary electron multiplying portion 23. Since a predetermined voltage is applied between the photocathode 1 and the first dynode, the photoelectrons are accelerated and made incident into the first dynode, thereby generating many secondary electrons, which are again emitted in a vacuum. The secondary electrons emitted from the first dynode are made incident into a second dynode to generate many secondary electrons, which are again emitted in a vacuum. The above procedures are repeated, by which photoelectrons finally multiplied to approximately 10⁶ times are collected by the anode 25 and allowed to pass through a stem pin as a photoelectric current and output outside the photomultiplier.

In the photomultiplier, where a quantum efficiency of the photocathode is low, a signal will fluctuate greatly even if subsequently multiplied by the secondary electron multiplying portion, thus resulting in a failure of obtaining a higher sensitivity. The electron tube 5 of the present embodiment uses the photocathode 1 capable of obtaining a high photoelectric conversion quantum efficiency. Thereby, it is possible to make a highly accurate measurement.

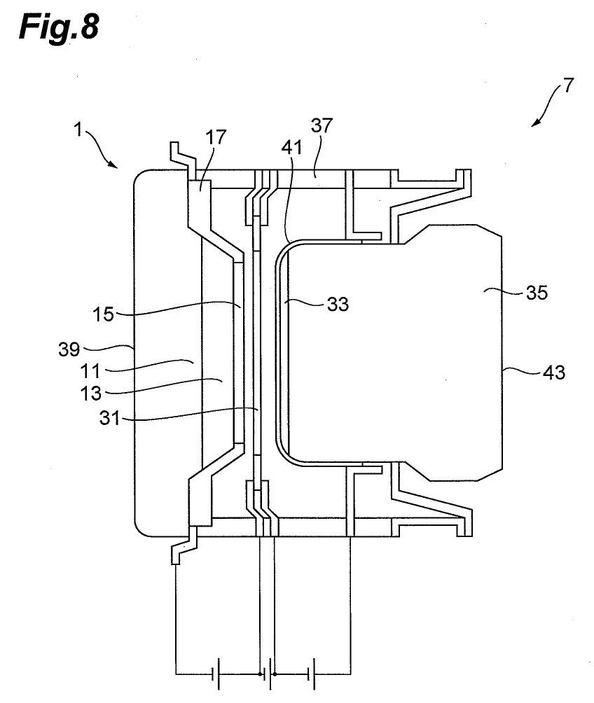

FIG. 8 is a drawing for explaining a cross sectional constitution of one embodiment of an electron tube 7 equipped with the photocathode 1. The electron tube 7 shown in FIG. 8 is an image intensifier and provided with a photocathode 1, a micro-channel plate (MCP) 31, a phosphor screen 33, an optical fiber plate 35 which is given as an output window 43, and a vacuum vessel 37 which accommodates them. A face free of the light absorbing layer 13 on the supporting substrate 11 of the photocathode 1 is press-fitted into the electron tube 7 from one end of a side tube of the vacuum vessel 37 so as to be in contact with an opening end of the electron tube 7. A region outside the supporting substrate 11 can be made with an insulating material such as quartz and glass. The micro-channel plate (MCP) 31 with a bundle of many channels having a hole several micrometers in diameter is provided inside the vacuum vessel 37 so as to oppose the surface layer 15 of the photocathode 1.

Further, the phosphor screen 33 is provided so as to oppose the photocathode 1 via the MCP 31, and the optical fiber plate 35 is arranged on the phosphor screen 33 so as to be in contact therewith. Still further, the anode 41 is provided to cover the surface of the phosphor screen 33 arranged so as to oppose the photocathode 1.

Hereinafter, a description will be given for the operation of the electron tube 7 which is an image intensifier. As with the photocathode 1 of the electron tube 5, incident light made incident into the photocathode 1 through the entrance window 39 excites photoelectrons inside the photocathode, by which the photoelectrons are emitted from the surface of the photocathode in a vacuum. The photoelectrons emitted in a vacuum are made in close proximity to the photocathode 1 and accelerated toward an incident face of the MCP 31 in which a positive potential is applied to the photocathode 1. The photoelectrons made incident into the MCP 31 are multiplied up to approximately 10⁴ times, while being transmitted inside the MCP 31, and emitted again from the output side of the MCP 31 in a vacuum. In addition, the MCP 31 is constituted to have a bundle of many channels with a hole several micrometers in diameter, and the photoelectrons are output from the side of an output face, with incident position information kept on the incident face of the MCP 31.

The photoelectrons emitted from the MCP 31 are in close proximity to an output face of the MCP 31 and made incident in an accelerated manner toward the phosphor screen 33 in which a positive electrode is applied to the output face of the MCP 31, thereby the phosphor screen 33 emits light. The thus light emitting light figure is output via the optical fiber plate 35 from the output window 43. Therefore, an image made incident into an entrance window can be multiplied and output from the output window 43, with two-dimensional information kept.

Since the electron tube 7 of the present embodiment uses the photocathode 1 capable of obtaining a high photoelectric conversion quantum efficiency, it is possible to visualize a light figure resulting from the ultraviolet region light and also make a highly accurate measurement. In addition, in any of the above described electron tubes, in place of the photocathode 1, the photocathode 3 can be applied.

The present invention shall not be limited to the above described embodiments but may be modified in various ways. In the electron tube 7 which is an image intensifier, the phosphor screen 33 is used as means for emitting light by using secondary electrons, to which the present invention shall not be, however, limited. Other elements may be usable in the present invention, as long as they are able to convert electrons to an image. For example, in place of the phosphor screen 33 and the optical fiber plate 35 arranged so as to be in contact therewith, an image pickup device such as a charge coupled device (CCD) is provided and secondary electrons are driven directly into the image pickup device to form an image, thereby obtaining similar effects.

Further, in the above described embodiment, the surface layer 15 is made with Cs and O, to which the present invention shall not be, however, limited. Cs, Rb, Na K or their oxides may also be usable in the present invention.

In the above described supporting substrate, the thickness is preferably within a range of 50 μm or more to 1000 μm or lower in general, with no particular upper limit given. This thickness is first effective in supporting mechanically a thin light absorbing layer (1 μm or lower). The light absorbing layer is very thin and therefore lower in mechanical strength. Thus, where no supporting substrate is provided, during manufacturing processes of a photoelectron surface or in assembly of an electron tube using the photoelectron surface, it is impossible to handle them. In order to provide strength necessary for handling them, the thickness of the supporting substrate should be preferably at least 50 μm or more and more preferably 100 μm or more.

What is claimed is:

1. A photocathode comprising:
a supporting substrate comprising a single-crystal compound semiconductor;
a light absorbing layer which is formed on the supporting substrate and smaller in energy band gap than the supporting substrate to absorb incident light transmitted through the supporting substrate, thereby generating photoelectrons; and
a surface layer which is formed on the light absorbing layer to lower a work function of the light absorbing layer, wherein the supporting substrate comprises Al₍₁₋ₓ₎GaₓN, 0≦X<1, and the light absorbing layer comprises a compound semiconductor comprising at least one material selected from the group consisting of Al, Ga and In, and N.

2. The photocathode according to claim 1, wherein the surface layer includes one or more types of alkaline metals or alkaline metal compounds.

3. The photocathode according to claim 1, wherein a composition ratio X of Al_{(1-X)}GaₓN which forms the supporting substrate is within a range of 0≦X<0.7.

4. The photocathode according to claim 1, further comprising a buffer layer interposed between the supporting substrate and the light absorbing layer, said buffer layer having an energy band gap not more than that of the supporting substrate.

5. The photocathode according to claim 1, wherein the supporting substrate is a plate-like member.

6. An electron tube comprising:
the photocathode according to claim 1;
an anode for collecting electrons emitted from the photocathode; and
a vacuum vessel for accommodating the photocathode and the anode.
